(19) United States
(12) Patent Application Publication
(10) Pub. No.: US 2025/0320598 A1
(43) Pub. Date: Oct. 16, 2025

(54) VANADIUM OXIDE DOPED TIN THIN FILMS FOR UNCOOLED INFRARED DETECTION

(71) Applicants: Lin Cong, Dover, DE (US); Mukti Rana, Middletown, DE (US)

(72) Inventors: Lin Cong, Dover, DE (US); Mukti Rana, Middletown, DE (US)

(73) Assignee: Delaware State University, Dover, DE (US)

(21) Appl. No.: 19/170,518

(22) Filed: Apr. 4, 2025

Related U.S. Application Data
(60) Provisional application No. 63/634,049, filed on Apr. 15, 2024.

(51) Int. Cl. C23C 14/08; C23C 14/58; C23C 16/40; C23C 16/56

(52) U.S. Cl. CPC C23C 14/083; C23C 14/5806; C23C 16/405; C23C 16/56

(57) ABSTRACT

A process for forming a thin film of vanadium-tin-oxide (VₓSn_{y}O_{z}) includes forming an alloy of the thin film of VₓSn_{y}O_{z}, by mixing: an x value of vanadium (V) in a range of 0.27≤x≤0.4, a y value of tin (Sn) in the range of 0.055≤y≤0.105, and a z value of oxygen (O) in the range of 0.49≤z≤0.687.

### GOVERNMENT RIGHTS

This invention was made with government support under the following grant numbers: W911NF1810448 awarded by the Army Research Office; FA9550-22-1-0534 awarded by the Air Force Office of Scientific Research; and IIP-2048602 awarded by the National Science Foundation (NSF). The government has certain rights in the invention.

### FIELD OF THE INVENTION

This invention relates to Vanadium Oxide Doped Tin (V—Sn—O) thin films for a microbolometer and a process of manufacturing thereof. It relates to the deposition, characterization and properties of V—Sn—O thin films for their electrical, optical, mechanical and morphological properties for the microbolometer's sensing layer. Microbolometers are infrared sensors which change their resistances when the temperature changes. The microbolometer operates in Midwave Infrared (MWIR, 3 to 5 μm) and Longwave Infrared (LWIR, 8 to 14 μm) wavelengths for detecting infrared (IR) radiation. The unique properties of V—Sn—O thin films will be used for uncooled IR detection.

### BACKGROUND OF THE INVENTION

Thermal IR detectors are heated by the incident IR radiation and provide detection through the change in a measurable parameter. For these types of detectors, wavelengths of interest are mainly in the atmospheric windows—ranging from 3 to 5 (MWIR) and 8 to 14 (LWIR) μm wavelength ranges, due to the high transmission through atmospheric air of more than 80% and peak IR emission of room temperature bodies is at 9-10 μm of wavelengths. Thermal detectors like microbolometers are being used contact-less temperature measurement, night vision cameras for defense, security and surveillance applications, search and rescue and many other thermal imaging applications because of their low-cost, better performance and compact size. A main factor in dictating how well a thermal detector will work is the detector's responsivity. Responsivity is the ability of the device to convert the incoming radiation into an electrical signal. Detector material properties influence this value; therefore, several main material properties are investigated which include temperature coefficient of resistance (TCR), optical bandgap, transmittance, reflectance and absorptance and resistivity in the wavelengths of interest. Other properties such as compatibility with complementary metal oxide semiconductor (CMOS) processing technology, low cost and reliability and stability of the material while exposed to infrared radiation are important.

The microbolometer's sensing materials are classified in two main categories—metals and semiconductors. Metals such as Ti, Ni or Ni—Fe alloys had been reported as bolometer's sensing layers.

Amorphous Si (a-Si) and Vanadium Oxide (VOₓ) are two of the most widely used materials for sensing layers of microbolometers These two materials suffer from low TCR and low absorption which yields lower figures of merits such as responsivity, detectivity, and noise equivalent temperature difference. By using various atomic compositions of Vanadium, Tin and Oxide in V—Sn—O thin films, this invention reports using V—Sn—O thin films for microbolometer's sensing layer.

For microbolometers made of semiconducting sensing layers (semiconducting microbolometers), thermal change on a material with a high TCR causes a change in electrical resistance, thus allowing a measurable parameter across the detector with heating and cooling. Once the microbolometer's sensing layer's temperature changes, there are three possible mechanisms of heat loss. First, heat is lost through conduction/convection through the atmosphere surrounding the detector thermometer, which is described below. This is minimized by vacuum packaging the detectors. Today, it has been a common practice to include the wafer-level vacuum packaging scheme for all commercially available microbolometers. Second, heat is lost through radiation. The selection of materials will impact this mechanism. However, the materials that are preferred for low heat loss also absorb less infrared radiation, which is not desirable. This mechanism represents the ultimate limit on the performance of the detector. Third, the heat is lost through thermal conduction through the supporting structure of the thermometer. The design of the supporting structure will minimize the thermal conductance of the structure.

The performance of an IR detector for imaging is most commonly described by a parameter called noise-equivalent temperature difference (NETD), which is the measurement of how well a thermal detector will distinguish between slight differences in thermal radiation in the image. The best cryogenically cooled quantum devices will have NETD values below 20 mK. Although no thermal uncooled detector has reached such low values, the theoretical limits of thermal IR detectors operating at ambient temperature are close to the values of cooled quantum detectors for wavelengths above 8 μm. Since thermal noise power increases as the square root of heat conduction, the heat conduction to the environment poses the largest limit in terms of detection. To lower this limit, the thermal bridges between detector to substrate and housing must be minimized. Also, lowering the heat capacity of the detector element by reducing the thickness of the detector structure leads to a large temperature change per radiation input, further reducing the effect of noise. Commercial microbolometers with a lens of a f-number equal to 1 has an NETD value of 35 mK. Micromachining has allowed further improvement of thermal detectors, with the most advanced IR Focal Plane Array (FPA) currently based on microbolometers of vanadium oxide and amorphous silicon, achieving NETD between 25 and 50 mK.

For a thermal detector, the sensitive element is referred to as the thermometer. The thermometer is typically thermally isolated from the substrate to improve the responsivity by suspending it above the substrate using micromachining techniques. The performance of a thermal detector depends upon the thermal capacity Cₜₕ, the rate at which thermal energy is lost through the thermal conductance of the structure, Gₜₕ, and the radiative thermal conductance, G_{rad}. The radiative thermal conductance for a gray body, assuming the emissivity is equal to the absorptivity, is given by equation G_{rad}=4ησAT³; where η is the average absorption of the detector, σ is the Stefan-Boltzmann constant, A is the surface area and T is the absolute temperature. The conductive/convective loss is neglected since the detector is typically operated in vacuum. The temperature change due to a sinusoidally modulated photon flux is given by:

$$Δ T = \frac{η Φ}{{{G}_{eff} ( 1 + {ω}^{2} {τ}_{th}^{2} )}^{1 / 2}} \qquad ( 1 )$$

Where, Φ is the radiant energy flux, is the angular modulation frequency of the incident radiation, and is the thermal time constant (Cₜₕ/Gₜₕ). The effective thermal conductance, G_{eff}, is obtained through a heat balance and is given by:

$${G}_{eff} = {G}_{th} + {G}_{rad} \pm α {P}_{bias} \qquad ( 2 )$$

Where, α is the TCR of the thermometer, P_{bias} is the power dissipated in the bias of the detector. The sign of the power bias term depends upon the type of bias. The “+” sign corresponds to the voltage bias case while the “−” sign corresponds to the current bias case. For the case of a semiconductive microbolometer, the TCR is negative, which means that the power dissipated in the detector effectively increases the effective thermal conductance G_{eff}.

There are other figures of merits than NETD for microbolometers which are described below:

Temperature coefficient of resistance (TCR): TCR exhibits how rapidly the resistance of the sensing material responds to a change in temperature and is expressed as

$$α = \frac{1}{R} \cdot \frac{dR}{dT} = \frac{1}{R} \frac{Δ R}{Δ T} = - \frac{{E}_{a}}{{kT}^{2}} \qquad ( 3 )$$

Here, Eₐ is the activation energy and k is the Boltzmann constant. TCR is a material property, so the higher the value, the better it is for IR uncooled detection.

Responsivity: Responsivity is a measure of the dependence of the signal output of a detector upon the input radiant power. The detector output signal may be current or voltage. Thus, the voltage responsivity, R_{ν}, is defined as the detector output voltage per unit of detector input power.

$${R}_{v} = \frac{η α {RI}_{b}}{{{G}_{th} ( 1 + {ω}^{2} {τ}^{2} )}^{1 / 2}} \qquad ( 4 )$$

Where, η, I_{b}, Gₜₕ, ω, and τ are the absorption coefficient, bias current, thermal conductance, angular frequency, and time constant of the device, respectively. The first three terms of the numerator in the right-hand side of equation (4) (η, α and R) depend on material properties of the microbolometer. Voltage responsivity is expressed in V/W while current responsivity is expressed in A/W. The voltage responsivity of the bolometer is increased by decreasing the thermal conductance of the structure. The thermal time constant of the microbolometer is in the millisecond range as it involves the thermal mass of the sensing layer which needs to heat up for change in resistance because of IR radiation.

Detectivity: Detectivity, D*, is the area normalized signal to noise ratio. It has the unit of cmHz^{1/2}/W. The detectivity is expressed by

$${D}^{*} = \frac{{R}_{v} \sqrt{{A}_{d} Δ f}}{Δ {v}_{n}} \qquad ( 5 )$$

where, Δνₙ is the total noise voltage observed in the electrical bandwidth Δf and is the sum of noises from the sensing element of the microbolometer—Johnson noise, random telegraph switching noise, 1/f-noise, generation and recombination noise. Higher responsivity represents higher detectivity.

Table 1 shows the list of materials used as the sensing layer of microbolometer infrared detector.

TABLE I
TCR and other figures of merit of bolometer sensing materials.

| | TCR | Detectivity | Responsivity | Resistivity | Pixel size |
|---|---|---|---|---|---|
| Material | (%/K) | (cmHz^{1/2}/W) | (V/W) | (Ω-cm) | (μm²) |
| V₂O₅ | 2.8 | 6 × 10⁵ | 36 | 1.7 | 200 × 800 |
| V_{0.95}W_{0.05} | 4.10 | 1 × 10⁹ | N/A | 40 | N/A |
| a-SiGe | −2 | N/A | N/A | ~40 | N/A |
| Poly-SiGe | −1.91 | 8.3 × 10⁸ | 15,000 | N/A | N/A |
| poly-SiGe (CVD | −2 | 2.31 × 10⁹ | 1.4 × 10⁴ | N/A | 25 × 25 |
| deposited) | | | | | |
| a-Si:H | 2.8-3.9 | N/A | 1 × 10⁶ | N/A | 48 × 48 |
| a-GeₓSi₁₋ₓO_{y} | −2.27-−8.69 | 8.27 × 10⁶ | 1.05 × 10⁴ | 4.22 × 10²- | 40 × 40 |
| | | | | 3.47 × 10⁹ | |
| Y—Ba—Cu—O | 4.02 | 1.6 × 10⁹ | 3.8 × 10⁵ | 32.42 | 7000 × 10000 |

In aspects of the present invention, the inventors observed that the thin film has a high absorption in the wavelength ranges of 0.9-4.0 μm range. The optical energy band gap (0.6 eV) of the thin film was using Tauc's equation. In addition to these, the inventors also found the variations of absorption coefficient (357299.48 m⁻¹-184046.47 m⁻¹) for the wavelength ranges between 0.9-4.0 μm, and the variations of refractive index (1.8-2.78), and the extinction coefficient (0.55-0.825) for the wave number ranges between 1500 cm⁻¹-7000 cm⁻¹. The present inventors found the thin film's resistivity to be 0.88 Ω-cm at room temperature by four-point probe method.

### SUMMARY OF THE INVENTION

The following presents a simplified summary of the invention in order to provide a basic understanding of some example aspects of the invention. This summary is not an extensive overview of the invention. Moreover, this summary is not intended to identify critical elements of the invention or to delineate the scope of the invention. The sole purpose of the summary is to present some concepts in a simplified form as a prelude to the more detailed description that is presented later.

Aspects of the present invention are focused on to overcome the problems mentioned above to obtain low noise and responsivity using V—Sn—O thin films for microbolometers by a simplified process and a method thereof and a microbolometer using the V—Sn—O thin films. The microbolometer encompasses a change in resistance on the sensing material due to the absorption of heat flux on it, causing a change across the sensing material's resistance to be measured across the electrodes.

The second objective of this invention to prepare stable V—Sn—O thin films for uncooled infrared detection with high reproducibility property and a process for manufacturing thereof.

The third objective of this invention is to provide V—Sn—O thin films which will increase the sensitivity of microbolometer and a process of manufacturing thereof using V—Sn—O thin films.

The fourth objective of this invention is to prepare V—Sn—O thin films for bolometer's sensing layer to reduce the overall fabrication cost of the device by providing a simpler process and method of manufacturing thereof, and a microbolometer using the V—Sn—O thin films.

According to an aspect of the invention, the thin films of VₓSn_{y}O_{z} comprise of vanadium (V), tin (Sn) and oxygen (O) elements with values of 0.27≤x≤0.4, 0.055≤y≤0.105, 0.49≤z≤0.687, respectively, with a thickness range from 95 nm to 270 nm.

In accordance with embodiments of the invention, the thin films of VₓSn_{y}O_{z} are deposited by co-sputtering of Sn and V targets in an argon (Ar) and oxygen (O) environment using a radio frequency sputtering system under room temperature. The thin films of VₓSn_{y}O_{z} are deposited on silicon or cover glass. The thin films of VₓSn_{y}O_{z} can also be deposited by a chemical vapor deposition process using various gases and precursors.

According to embodiments of the invention, the thin films of VₓSn_{y}O_{z} can have a thickness ranging from 95 nm to 300 nm, where an x value of vanadium (V), a y value of tin (Sn), and a z value of oxygen (O) are in the ranges of 0.27≤x≤0.4, 0.055≤y≤0.105, 0.49≤z≤0.687, respectively.

According to embodiments of the invention, the atomic composition of the thin films of VₓSn_{y}O_{z}, where 0.27≤x≤0.4, 0.055≤y≤0.105, 0.49≤z≤0.687, can be controlled by changing the power of the DC sputter, power of the radio frequency sputter, process pressure, ratio of the gases' flow during the deposition and substrate temperature during the deposition.

According to embodiments of the invention, the thin films of V—Sn—O are thermally annealed and passivated in an oxygen or foaming gas environment at temperature ranging from 400° C. to 550° C. This thermal treatment is necessary to reduce the electrical noise which has significant impact on the performance of the microbolometer.

According to another aspect of the invention, there is an infrared detector comprising of bolometer. The bolometer comprises thin films of VₓSn_{y}O_{z} as the sensing layer which has V, Sn and O elements with values of 0.27≤x≤0.4, 0.055≤y≤0.105, 0.49≤z≤0.687, respectively.

According to embodiments of the invention, as the sensing layer of the microbolometer, the thin films of V—Sn—O have a thickness ranging from 95 nm to 300 nm.

As described above, in embodiments of the present invention, the V—Sn—O film for a bolometer is prepared by a simplified process having a low noise value.

Further, in embodiments of the present invention, stable and high reproducibility properties are obtained.

According to embodiments of the invention, since the V—Sn—O films are manufactured using cheap equipment and a simplified process, the cost of fabricating the microbolometer device will be reduced.

Embodiments of the present invention will increase the sensitivity of microbolometer devices using V—Sn—O films.

### BRIEF DESCRIPTION OF THE DRAWINGS

The foregoing and other aspects of the present disclosure will become apparent to those skilled in the art to which the present disclosure relates upon reading the following description with reference to the accompanying drawings, in which:

FIG. 1 is a flowchart illustrating the process for preparing the VₓSn_{y}O_{z} thin films, where 0.27≤x≤0.4, 0.055≤y≤0.105, 0.49≤z≤0.687.

FIG. 2 illustrates a surface profile of V—Sn—O thin films determined by atomic force microscopy.

FIG. 3 illustrates the atomic composition of V—Sn—O thin films determined by energy dispersive spectroscopy at 5 kV.

FIG. 4 illustrates the refractive index and the extinction coefficient of a V—Sn—O thin film.

FIG. 5 illustrates the transmittance, reflectance and absorptance of a V—Sn—O thin film.

FIG. 6 illustrates the optical band gap of a V—Sn—O thin film determined from transmittance, reflectance and absorptance data.

FIG. 7 is an arrhenius plot at various temperatures to determine the activation energy of V—Sn—O thin films.

FIG. 8 illustrates variations of the temperature coefficient of resistance (TCR) with temperature.

FIG. 9 illustrates a cross section of a V—Sn—O microbolometer.

### DETAILED DESCRIPTION OF THE INVENTION

The invention will now be described by reference to exemplary embodiments and variations of those embodiments. Although the invention is illustrated and described herein with reference to specific embodiments, the illustrated examples are not intended to be limited to the details shown and described. Rather, various modifications may be made in the details within the scope and range of equivalents of the claims and without departing from the invention. For example, one or more aspects of the disclosed embodiments can be utilized in other embodiments and even other types of devices. Moreover, certain terminology is used herein for convenience only and is not to be taken as a limitation.

Described herein are the microbolometer elements and processes and methods for forming the same. The sensing layer of microbolometer is fabricated using various atomic compositions of Vanadium, Tin and Oxygen to form an alloy of vanadium-tin-oxide (V—Sn—O). The variation in atomic composition in the alloy of V—Sn—O will allow the materials' properties to be varied. The variation of the atomic composition in V—Sn—O alloy will vary the fundamental material properties such as activation energy and carrier mobility. This way the key microbolometer device figures of merits such as resistivity, TCR, responsivity, absorption in IR region of interest, noise, detectivity, and noise equivalent temperature difference, are varied and optimized for better device performance.

TCR is one of the important properties of microbolometer and it defines the sensitivity of the microbolometer device which is defined as change in electrical resistance of the device with change in temperature. The greater the value of TCR, the better will be the sensitivity of the microbolometer device. Herein, the present inventors used oxygen to bond with vanadium and tin to increase the TCR among other properties. In the preferred embodiment, the present inventors found that the TCR varied between −1.54%/k to −1.89%/k for the temperature ranges 283 k to 313 k.

The atomic composition of the microbolometer sensing layer made of VₓSn_{y}O_{z} thin film layer consists of transition metal material (V) and semiconductor material (Sn) forming an alloy and bonded with oxygen where 0.27≤x≤0.4, 0.055≤y≤0.105, 0.49≤z≤0.687. Oxygen or forming gas (95% nitrogen and 5% hydrogen) or fluorine is added to the alloy VₓSn_{y}O_{z} to passivate the dangling bonds created between the constituent elements where 0.27≤x≤0.4, 0.055≤y≤0.105, 0.49≤z≤0.687. Oxygen or forming gas (95% nitrogen and 5% hydrogen) or fluorine will be in the gaseous, liquid or other forms which will be used to passivate the VₓSn_{y}O_{z} thin films where 0.27≤x≤0.4, 0.055≤y≤0.105, 0.49≤z≤0.687. The passivation is done with annealing process at an elevated temperature (>250° C.) in a furnace or at a rapid thermal annealing system. Annealing can release the superfluous oxygen atoms from the VₓSn_{y}O_{z} thin film and bonding with the vanadium and tin atoms in the VₓSn_{y}O_{z} thin film so that increasing the crystallization of the VₓSn_{y}O_{z} thin film and changing the resistance. In oxygen environment, the main composition is V₂O₅. In foaming gas environment, the main composition is VO₂ or V₂O₅ which depends on the ratio of argon (Ar) and oxygen (O₂) in deposition processes and the annealing time. Because the VₓSn_{y}O_{z} thin film can get extra oxygen atom from the oxygen environment. In one embodiment, the present inventors disclose the atomic composition of VₓSn_{y}O_{z} where the value of “x” is the atomic percentage of V in that alloy. The value of “x” varies between 0.27 to 0.4, the value of y varies between 0.055 to 0.105. The value of “z” varies between 0.49 to 0.687.

In another embodiment, the thin film of VₓSn_{y}O_{z} will be deposited using the sputtering process, where 0.27≤x≤0.4, 0.055≤y≤0.105, 0.49≤z≤0.687. The sputtering process consists of radio frequency as well as direct current method.

Exemplary embodiments of the present invention are described in detail hereinafter. The drawings presented here, will explain the current invention better although it should be noted that the present invention is not limited to the drawings.

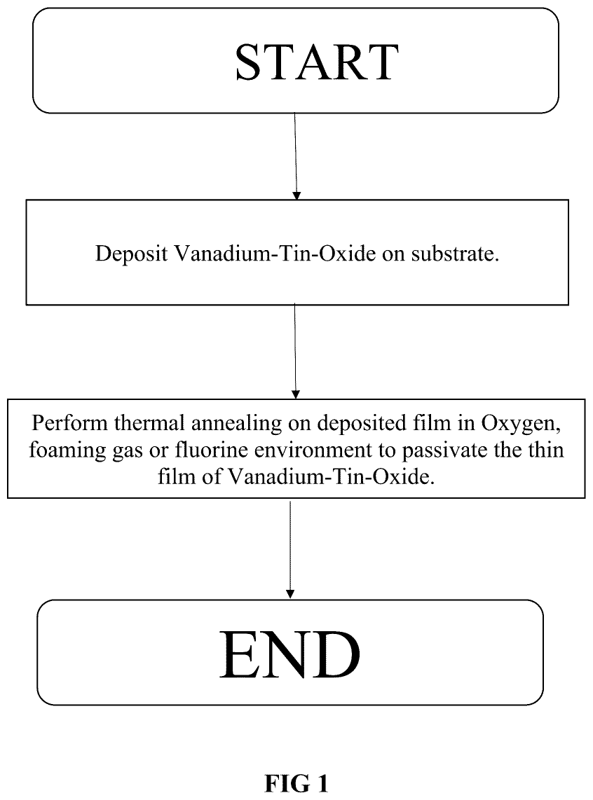

FIG. 1 is a flow chart illustrating a process for fabricating the VₓSn_{y}O_{z} thin film to be used as the sensing layer of the microbolometer in accordance with an embodiment of the present invention where 0.27≤x≤0.4, 0.055≤y≤0.105, 0.49≤z≤0.687. FIG. 1 shows the process for manufacturing a VₓSn_{y}O_{z} thin film for a bolometer's sensing layer where 0.27≤x≤0.4, 0.055≤y≤0.105, 0.49≤z≤0.687. A preferred embodiment of one aspect of the present invention includes three steps: The first step includes cleaning a substrate by using acetone, methanal, and isopropanol. The second step includes deposition of VₓSn_{y}O_{z} thin film on the substrate. The third step includes passivation of VₓSn_{y}O_{z} thin film with presence of preferred gases at an elevated temperature than the room temperature for some period of time where 0.27≤x≤0.4, 0.055≤y≤0.105, 0.49≤z≤0.687. In accordance with the invention, the thin films of are deposited VₓSn_{y}O_{z} by co-sputtering of Sn and vanadium targets in the Ar+O environment using a radio frequency sputtering system. The films are deposited on silicon or cover glass substrates. The thin films are also deposited by DC sputtering or metal-organic chemical vapor deposition (MOCVD) or chemical vapor deposition process using V, Sn and O based gases and precursors.

In this case, the RF sputter for both vanadium target and tin target using argon (Ar) or nitrogen (N) plasma. The thickness of the VₓSn_{y}O_{z} thin film may ranges from 95 nm to 270 nm. According to the invention, the thin films of VₓSn_{y}O_{z} comprise of V, Sn and O elements with values of where 0.27≤x≤0.4, 0.055≤y≤0.105, 0.49≤z≤0.687. When the z of VₓSn_{y}O_{z} is >0.687, the electric resistance of the thin film is too large. Accordingly, it is not suitable for the bolometer applications. When the oxygen component z is less than 0.49 or the tin component y is greater than 0.105, the electric resistance is too small and the TCR value is small as well, thereby making it not suitable for the bolometer. Because the SnO₂ has a lower resistivity and lower TCR than vanadium oxide. For the current invention, through the controlling of the ratio of argon (Ar) and oxygen (O₂) we obtained non-crystalline VₓSn_{y}O_{z} thin film at room temperature. Then, thermal annealing the VₓSn_{y}O_{z} thin film in the forming gas or oxygen environment is used to crystallize the VₓSn_{y}O_{z} thin film. The temperature range of the thermal annealing is between 400° C. to 550° C. This thermal treatment is necessary to reduce the electrical noise which has significant impact on the performance of microbolometer.

A turbo pump evacuated the chamber to a base pressure of 4×10⁻⁶ Torr or less before sputtering. The Vanadium (V) target and Tin (Sn) target both were used simultaneously to deposit the VₓSn_{y}O_{z} thin films on silicon or glass substrates which may be flexible or rigid. The deposition will be done by using DC and/or RF sputter. The DC sputter and RF sputter use Argon (Ar) or nitrogen (N₂) plasma. The deposition process takes place in an oxygen atmosphere. The sputtering will take as long as 2 hours but, in this case, the V and Sn targets were sputtered for 60-100 minutes. Vanadium target was sputtered at 50 W while Sn was sputtered at 6 W. The preferred embodiment includes a design of material for each of the layers of the microbolometer whose composition and thickness leads to high figures of merits. Vanadium Tin Oxide (V—Sn—O) was created by co-sputtering V with Sn targets in the Ar+O environment using a radio frequency sputtering system.

Radio frequency sputtering system is defined as a technique involved in alternating the electrical potential of the current in the vacuum environment at radio frequencies to avoid a charge building up on certain types of sputtering target materials, which over time will result in arching into the plasma that spews droplets creating quality control issues on the thin films and will even lead to the complete cessation of the sputtering of atoms terminating the process. In this case, V at 50 W and Sn at 6 W were sputtered for 60 minutes with a deposition rate of 0.4 Å per second on a glass substrate.

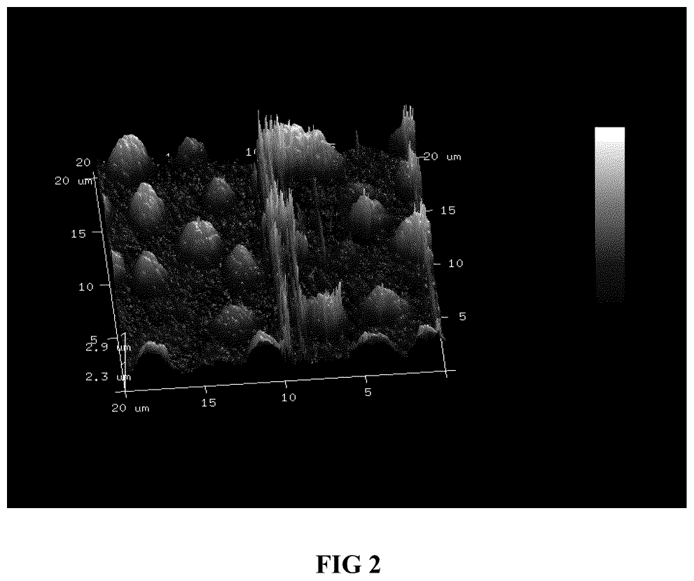

FIG. 2 is the surface profile of VₓSn_{y}O_{z} thin films determined by atomic force microscopy where x=0.398, y=0.099, z=0.502. This surface profile enables us to see the roughness of the film. Such roughness will affect the optical properties of the film. In the preferred embodiment, the average of surface roughness in the z-direction for the V—Sn—O thin films is 139 nm. Excess roughness in the thin film creates non-linearity in the film thickness and the overall the resistance of the film varies as well. This variation of film resistance creates fluctuation in temperature coefficient of resistance, responsivity, detectivity and other figures of merits.

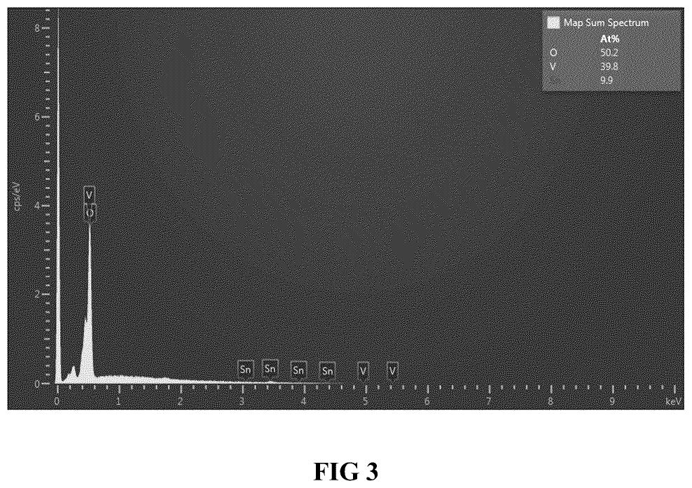

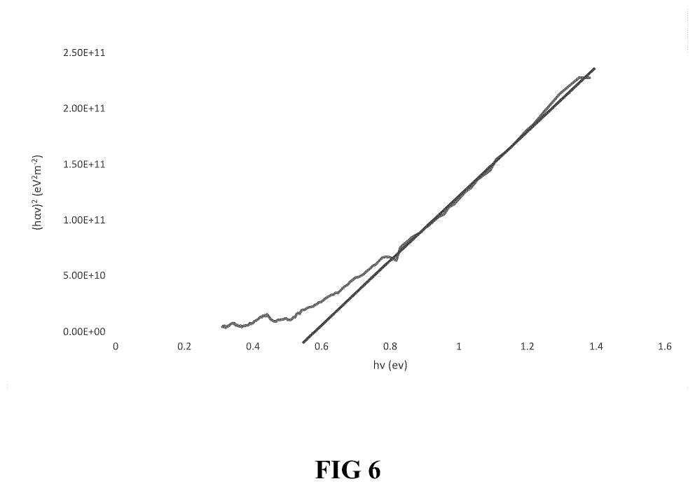

FIG. 3: shows the atomic Composition of VₓSn_{y}O_{z} thin films determined by energy dispersive spectroscopy done at 5 kV where 0.27≤x≤0.4, 0.055≤y≤0.105, 0.49≤z≤0.687. The unique peaks in FIG. 3 indicate the estimated value of abundance of the different elements in the thin film. In the preferred embodiment, VₓSn_{y}O_{z} thin films consist of 50.2% Oxygen, 9.9% Tin, 39.8% Vanadium where 0.27≤x≤0.4, 0.055≤y≤0.105, 0.49≤z≤0.687. As mentioned earlier, the thin films of VₓSn_{y}O_{z} comprise of V, Sn and O elements. In the preferred embodiment, the values ranges are as follows: 0.27≤x≤0.4, 0.055≤y≤0.105, 0.49≤z≤0.687. Determination of atomic composition of the constituent elements in the thin films of V—Sn—O is crucial for not only the correct elemental composition in V—Sn—O but also for unique behavior of VₓSn_{y}O_{z} thin film (where 0.27≤x≤0.4, 0.055≤y≤0.105, 0.49≤z≤0.687) for sensing layer of microbolometer. Addition of Sn in the V—Sn—O compound results in added absorption in the wavelength ranges 2 to 4.5 μm which is shown in FIG. 6.

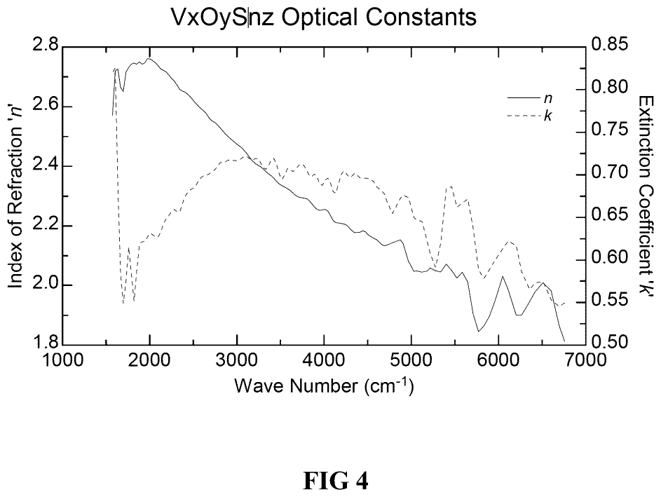

FIG. 4 indicates the refractive index and extinction coefficient of the V—Sn—O thin film. Refractive index is a number that describes how light propagates through that medium, while the extinction coefficient indicates several different measures of the absorption of light in a medium. Extinction coefficient refers to a measure of the rate of decrease in the intensity of electromagnetic radiation (as light) as it passes through a given substance.

Extinction coefficient k(λ) is given by:

$$k ( λ ) = \frac{a λ}{4 π} \qquad ( 6 )$$

Where a is the absorption coefficient, λ is the wavelength.

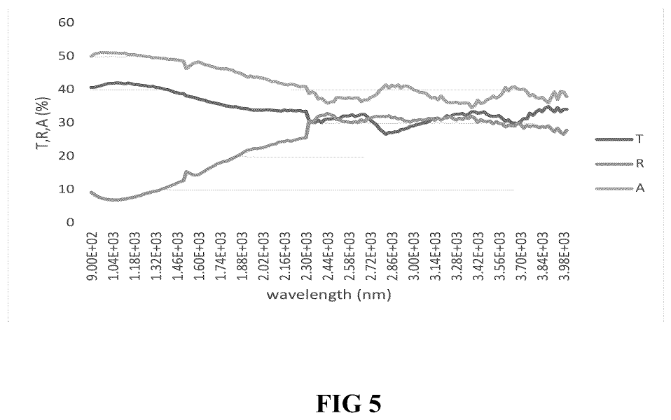

Reflective index n(λ) is the measure of the propagation of a ray of light as it passes from one medium to another and it was also derived by:

$$n ( λ ) = {n}_{s} ( λ ) {( \frac{1 + \sqrt{R}}{1 - \sqrt{R}} )}^{0.5} \qquad ( 7 )$$

Where, nₛ is the refractive index of the substrate (cover glass in our case), and R is the Reflectance. The refractive index for V—Sn—O varied between 1.8 to slightly under 2.8 for the wave number ranges between 1000 cm⁻¹ to 7000 cm⁻¹. These values are different from pure V, Sn or their oxides. The extinction coefficient varied between 0.55 to 0.825 for the wave number ranges between 1000 cm⁻¹ to 7000 cm⁻¹. The values of the extinction coefficient are also different from pure V, Sn or their oxides. The values of extinction coefficient and refractive index at various wavelengths determines the absorption, reflection and transmission through the thin films. The absorption in the film at a particular wavelength is crucial because of the absorption the thin films' temperature changes and the TCR. The values of absorption coefficient along with the reflection coefficient and transmittance at various wavelength are illustrated in FIG. 5.

FIG. 5 illustrates the transmittance, reflectance and absorptance of VₓSn_{y}O_{z} thin film, where 0.27≤x≤0.4, 0.055≤y≤0.105, 0.49≤z≤0.687. These measurements were carried out using monochromator, infrared (IR) light source, pyroelectric detector, mechanical chopper, lock-in amplifier and computer. Infrared (IR) light signal was generated using an IR source which came out of the monochromator and was chopped at 40 Hz. Results of peaks were recorded from lock-in amplifier in order to derive corresponding transmittance and reflectance were measured between the wavelength ranges 0.9-4.0 μm. Kirchhoff's law was then used to calculate the absorptance.

Transmittance τ(λ) through a thin film is expressed as the ratio of transmitted flux (ϕ_{λt}) to the incident flux (ϕ_{λi})

$$τ ( λ ) = \frac{{ϕ}_{λ t}}{{ϕ}_{λ i}} \qquad ( 8 )$$

where, λ is the wavelength.

Kirchhoff's law relating to absorptance (α), transmittance (τ) and reflectance (ρ) is expressed as:

$$a + τ + ρ = 1 \qquad ( 9 )$$

Absorption coefficient is a measure of the rate of decrease in the intensity of electromagnetic radiation (as light) as it passes through a given substance. For application as the sensing layer of microbolometer, the absorption value needs to be as high as possible. Higher absorption in the sensing layer will heat up the material and then the resistance of the material will reduce. So, the higher absorption is associated with greater sensitivity. The addition of Sn in VxSnyOz thin films increase the absorption in the wavelength ranges between 2 to 4.5 μm where 0.27≤x≤0.4, 0.055≤y≤0.105, 0.49≤z≤0.687.

FIG. 6 is Optical band gap of VₓSn_{y}O_{z} determined from transmittance, reflectance and absorptance data which shown earlier. Extrapolation of (αhν)^{1/2}=0 of linear portion in the plot of (αhν)^{1/2} versus the photon energy hν, gave the value of optical bandgap as mentioned in FIG. 6 where 0.27≤x≤0.4, 0.055≤y≤0.105, 0.49≤z≤0.687. To determine the optical bandgap, the present inventors used Tauc's equation for direct bandgap semiconductor which is expressed below:

$$α hv = {B ( hv - {E}_{g} )}^{1 / 2} \qquad ( 10 )$$

Where B is a constant, hν is the photon energy and E_{g} is the energy band gap. (αhν)² was graphed as a function of hν and the energy band gap was determined at the hν value where α=0. Optical bandgap is an important parameter for optical detectors such as microbolometers. The optical bandgap of V—Sn—O in this case is 1.0 eV which is unique for the V_{0.398}Sn_{0.099}O_{0.502} thin film before annealing. The optical bandgap of V—Sn—O is 0.6 eV for the V_{0.398}Sn_{0.099}O_{0.502} thin film after annealing. The thermal annealing will improve the crystallinity of the V—Sn—O thin film, decrease the crystal defects so that the band gap was decreasing. The optical bandgap plays an important role in optoelectronic properties of the material. When the photon falls on top of the material, if its energy is higher than the optical bandgap then it creates and electron hole pair. This is the principle of operation for a photon detector. For thermal detectors like microbolometers, the detector material's temperature rises and the resistivity of the material changes. Hence, electrical bandgap is an inherent property of the material V—Sn—O.

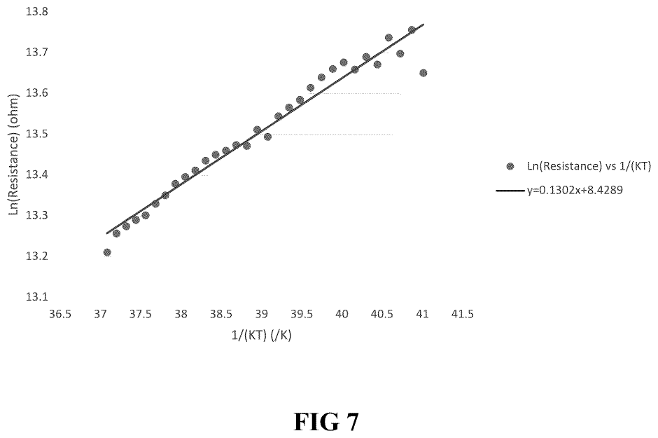

FIG. 7 Illustrates Arrhenius plot at various temperature to determine the activation energy of VₓSn_{y}O_{z} thin films where 0.27≤x≤0.4, 0.055≤y≤0.105, 0.49≤z≤0.687. Activation energy is the minimum energy required to cause a process (such as a chemical reaction) to occur. It is expressed using Arrhenius formula as follows:

$$k = - \frac{{E}_{a}}{R} ( \frac{1}{T} ) + ln A \qquad ( 11 )$$

where, k represents the rate constant, Eₐ is the activation energy, R is the gas constant (8.3145 J/K mol), and T is the temperature expressed in Kelvin. A is known as the frequency factor, having units of L mol⁻¹ s⁻¹, and takes into account the frequency of reactions and likelihood of correct molecular orientation.

Four-point probe instrument was used to measure average resistance of the film by passing current through the outside two points of the probe and measuring the voltage across the inside two points. This resistance is called sheet resistance (Rₛ).

If the spacing between the probe points is constant, and the conducting film thickness is less than 40% of the spacing, and the edges of the film are more than 4 times the spacing distance from the measurement point, the average resistance of the film or the sheet resistance is given by:

$${R}_{s} = 4.53 \times V / I \qquad ( 11 )$$

Total resistance R is given by:

$$R = {R}_{s} * t \qquad ( 12 )$$

Where, Rₛ is the measured sheet resistance and t is the films thickness. From FIG. 7 it is seen that the plot of natural logarithm of total resistance (R) versus 1/kT is a straight line and the slope of the straight line provides the value of the activation energy associated with this process. The higher the activation energy, higher will be the TCR associated with it. The activation energy for V_{0.398}Sn_{0.099}O_{0.502} thin film is 0.1302 eV.

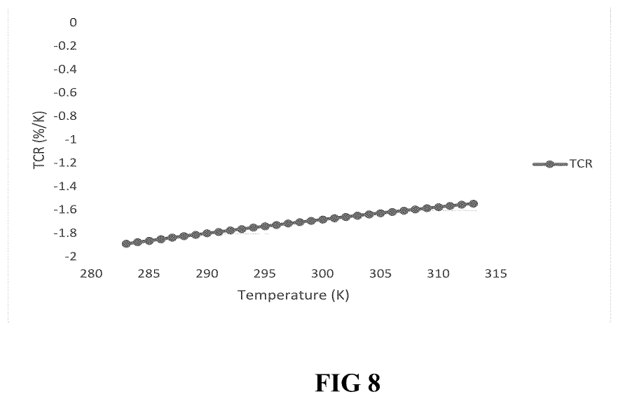

FIG. 8 illustrates the variations of temperature coefficient of resistance (TCR) for the V—Sn—O thin film is determined by measuring the resistances values over an appropriate temperature range in Kelvin. The TCR is calculated as the average slope of the resistance value over this interval. TCR exhibits how rapidly the resistance of the sensing material responds to a change in temperature and is expressed as:

$$α = \frac{1}{R} \cdot \frac{dR}{dT} = \frac{1}{R} \frac{Δ R}{Δ T} = - \frac{{E}_{a}}{{kT}^{2}} \qquad ( 13 )$$

Here, Eₐ is the activation energy and k is the Boltzmann constant.

TCR is a material property, so the higher the value, the better it is for IR uncooled detection. The room temperature (301K) TCR value is −1.21%/K. Also, at 283 K the TCR is −1.89%/K. The resistance of the V_{0.398}Sn_{0.099}O_{0.502} thin film varied between 943 kilo-Ohm to 546 kilo-ohm for the temperature range between 283 K to 313 K. This resistance range is considered as medium and very crucial for integration of this microbolometer device with the complementary metal oxide semiconductor (CMOS) circuit. The high value of TCR will yield high responsivity and detectivity and better device performance.

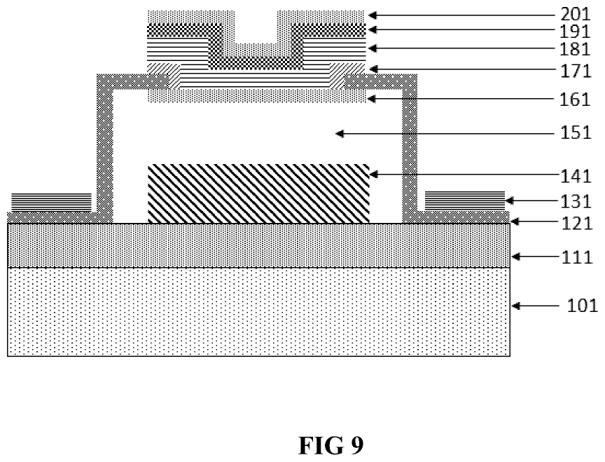

FIG. 9 shows the cross-sectional view of the microbolometer using V—Sn—O sensing layer. The substrate 101 in this case is Silicon. The depositions of different layers other than the Al and polyimide were done by a RF magnetron sputtering system equipped with a turbo pump and a three-inch target holder. Prior to sputtering, the process chamber was evacuated to 3×10⁻⁶ Torr by the turbo pump. Sputtering was done at 4 mTorr pressure. An Ar flow of 30 SCCM was used in every sputtering process other than deposition. In fabricating the VₓSn_{y}O_{z} bolometer, lift off technique was used for patterning all the films because of its simplicity where 0.27≤x≤0.4, 0.055≤y≤0.105, 0.49≤z≤0.687.

The fabrication of the bolometer starts by depositing 400 nm of silicon nitride 111 on a cleaned lightly doped p-type, three-inch diameter silicon wafer 101. This layer of silicon nitride 111 serves as the electrical insulation for the substrate and would withstand all the solvents used in next fabrication steps. Then a 400-nm-thick layer of Al layer 141 was deposited by thermal evaporation and patterned. The cryo pump of the evaporator was cooled down to 20 K after which the sample was mounted. The chamber was evacuated to 1×10⁻⁶ Torr prior to evaporation. A deposition rate of 5 angstrom/sec was achieved at 100 Ampere of applied current. To perform the lift off, negative resist NR7-1500P from Futurrex Corporation was spin coated on the wafer at 3000 rpm for 30 seconds. Then the wafer was prebaked at 150° C. for 60 seconds on a hot plate and exposed under the ultraviolet light. A post exposure bake for 60 seconds was done at 120° C. on a hot plate. Then the resist was developed in RD6-a negative resist developer from Futurrex Corporation for 50 seconds. The resist thickness was found to be about 1.8 μm after developing. This was found to be thick enough to lift off 0.4-μm-thick Al layer 141. After depositing Al film, the wafer was kept in 1165 photo resist striper for about two hours to complete the lift off process. The wafer was then rinsed with acetone, methanol, and DI water followed by a blow dry in nitrogen to make it clean. This Al layer 141 would serve as a mirror for reflecting the infrared rays and form the basis of an optically resonant cavity.

A sacrificial layer 151 of photo definable polyimide PI-2737 from HD Microsystems was spin coated, patterned by conventional photolithography and wet etching process. The polyimide was cured in the convection oven. After curing the polyimide thickness was found 2.2 μm. For patterning, the polyimide was spin coated at a speed of 1650 rpm for 60 seconds. Then it was baked on two step hot plate. In first step, it was baked at 70° C., while in second step it was baked at 100° C., both for three minutes. Then it was exposed in ultraviolet light. For developing polyimide, developer DE 9040 along with rinse solution RI 9180, both from HD Microsystem, were used. To store these solutions and complete developing process, four tanks and one squeeze bottle were used. First two of the four tanks were filled with 100% DE 9040 solution, third tank was filled with 50% DE 9040 and 50% RI 9180 solutions, fourth tank was filled with 25% DE 9040 and 75% RI 9180 solutions, while the squeeze bottle was filled with 100% RI 9180 solution. The wafer was kept inside the first two tanks for 10 seconds and agitated ultrasonically. Then it was transferred to the second and third tank respectively where it was kept for 15 seconds in each of them. Then the wafer was rinsed with RI 9180 solution for 20 seconds, by holding it vertically to remove all the polyimide flakes. By using four tanks instead of one tank, the problem of flakes generation was solved. The polyimide thickness at that point was about 5.3 μm. This was then cured in an oven at 250° C. for four hours in nitrogen ambient. The temperature was ramped slowly (from room temperature to 250° C. in one and half hours) to avoid possible thermal stress in the film.

To achieve low thermal mass, the sensing layer of VₓSn_{y}O_{z} 181 was made 0.145 μm thick. In order to make the sensing layer mechanically strong as well as free of warping, a sandwich structure of VₓSn_{y}O_{z} was made employing silicon nitride where, 0.27≤x≤0.4, 0.055≤y≤0.105, 0.49≤z≤0.687. The sandwich layers increase the thermal mass of the detector. However, they were found to be necessary, since the first type of the bolometers were fabricated without silicon nitride sandwich layers, and they were found to be warped after removing the sacrificial polyimide. To achieve the sandwich structure, first the bottom silicon nitride layer 161 was deposited and patterned. The thickness of this layer was set to 100 nm. Silicon nitride was chosen for this case, because silicon nitride is known to passivate silicon dioxide, although in current work it was not observed any significant effect of passivating the VₓSn_{y}O_{z} sensing layer 181 with silicon nitride where, 0.27≤x≤0.4, 0.055≤y≤0.105, 0.49≤z≤0.687. Next, a 200-nm-thick NiCr (20% Ni, 80% Cr) electrode arm 121 was deposited and patterned. NiCr has very low thermal conductivity, and thus provides good thermal isolation between bolometer thermometer and substrate.

To form an Ohmic contact with p-type VₓSn_{y}O_{z}, a 50-nm-thick Ni film 171 was deposited on top of NiCr arm and patterned where 00.27≤x≤0.4, 0.055≤y≤0.105, 0.49≤z≤0.687. Then, the sensing layer of VₓSn_{y}O_{z} was deposited in an Ar:O₂ environment from targets of V and Sn where 00.27≤x≤0.4, 0.055≤y≤0.105, 0.49≤z≤0.687. Next, a 14-nm-thick NiCr absorber 191 was deposited. Then the top silicon nitride layer of 100 nm thickness 201 was deposited. All three top layers, VₓSn_{y}O_{z} sensing layer 181, NiCr absorber 191, and top silicon nitride layer 201 were lifted off together. Finally, a 300-nm-thick Ni bond-pad-layer 131 was deposited on top of NiCr for the simplicity of bonding the device ultrasonically. At this point, the bolometer fabrication was completed. The sacrificial layer of polyimide under the bolometer was not removed for the sake of simplicity in device fabrication.

Although the invention is illustrated and described herein with reference to specific embodiments, the invention is not intended to be limited to the details shown. Rather, various modifications may be made in the details within the scope and range of equivalents of the claims and without departing from the invention.

1. A process for forming a thin film of vanadium-tin-oxide (VₓSn_{y}O_{z}), the process comprising:
forming an alloy of the thin film of VₓSn_{y}O_{z}, by mixing:
an x value of vanadium (V) in a range of 0.27≤x≤0.4,
a y value of tin (Sn) in the range of 0.055≤y≤0.105, and
a z value of oxygen (O) in the range of 0.49≤z≤0.687.

2. The process of claim 1, further comprising depositing the thin film of VₓSn_{y}O_{z} on a substrate by one of radio frequency sputtering, direct current sputtering, chemical vapor deposition, or metal organic chemical vapor deposition techniques.

3. The process of claim 2, wherein the thin film of VₓSn_{y}O_{z} is deposited in an argon (Ar) and oxygen (O) environment by a radio frequency sputtering method.

4. The process of claim 1, further comprising a thermal annealing of the thin film of VₓSn_{y}O_{z} at temperature ranges from 400° C. to 550° C.

5. The process of claim 4, wherein the thermal annealing uses process gases including forming gas, flourine or oxygen to reduce an electrical noise and improve a crystallinity of the thin film.

6. A thin film comprising vanadium-tin-oxide (VₓSn_{y}O_{z}) with an atomic composition of:
an x value of vanadium (V) in a range of 0.27≤x≤0.4,
a y value of tin (Sn) in the range of 0.055≤y≤0.105, and
a z value of oxygen (O) in the range of 0.49≤z≤0.687.

7. The thin film of claim 6, wherein a refractive index of the thin film varies between 1.8 and 2.78, and an extinction coefficient of the thin film varies between 0.55 and 0.825 for a wave number from 1500 cm⁻¹ to 7000 cm⁻¹.

8. The thin film of claim 6, wherein a transmittance, a reflectance and an absorptance of the thin film varies between 26.7% to 42.1%, 6.9% to 32.9%, and 34.6% to 51.2%, respectively, for wavelength ranges of 0.9 μm to 4.0 μm.

9. The thin film of claim 6, wherein an optical bandgap of the thin film varies between 0.6 eV and 1 eV.

10. The thin film of claim 6, wherein an activation energy of the thin film has a value between 0.0647 eV to 0.1523 eV depending on the atomic composition of the thin film.

11. The thin film of claim 6, wherein a coefficient of Resistance (TCR) varies in a range of −1.54%/K to −1.89%/K for temperature ranges 283K to 313K.

12. A process for manufacturing a microbolometer, the method comprising: fabricating a sensing layer of the microbolometer by mixing an alloy of a thin film of vanadium-tin-oxide (VₓSn_{y}O_{z}) on a substrate, wherein an atomic composition of the alloy comprises:
an x value of vanadium (V) in a range of 0.27≤x≤0.4,
a y value of tin (Sn) in the range of 0.055≤y≤0.105, and
a z value of oxygen (O) in the range of 0.49≤z≤0.687.

13. The process of claim 12, further comprising depositing the thin film on a substrate by one of radio frequency sputtering, direct current sputtering, chemical vapor deposition, or metal organic chemical vapor deposition techniques.

14. The process of claim 13, wherein the thin film of VₓSn_{y}O_{z} is deposited in a mixed argon (Ar) and oxygen (O₂) environment by a radio frequency sputtering method.

15. The process of claim 12, further comprising a thermal annealing of the thin film of VₓSn_{y}O_{z} at temperature ranges from 400° C. to 550° C.

16. The process of claim 15, wherein the thermal annealing uses process gases including forming gas or oxygen to reduce an electrical noise and improve a crystallinity of the thin film.

17. The process of claim 12, wherein a refractive index of the thin film varies between 1.8 and 2.78, and an extinction coefficient of the thin film varies between 0.55 and 0.825 for a wave number from 1500 cm⁻¹ to 7000 cm⁻¹.

18. The process of claim 12, wherein a transmittance, a reflectance and an absorptance of the thin film varies between 26.7% to 42.1%, 6.9% to 32.9%, and 34.6% to 51.2%, respectively, for wavelength ranges of 0.9 μm to 4.0 μm.

19. The process of claim 12, wherein an optical bandgap of the thin film varies between 0.6 eV to 1 eV.

20. The process of claim 12, wherein an activation energy of the thin film has a value between 0.0647 eV to 0.1523 eV depending on the atomic composition of the thin film.

21-24. (canceled)
